(19) United States
(12) Patent Application Publication
(10) Pub. No.: US 2017/0231099 A1
(43) Pub. Date: Aug. 10, 2017

(54) Electrical Breaks in PCB Vias

(71) Applicant: Dell Products, LP, Round Rock, TX (US)

(72) Inventors: Kevin W. Mundt, Austin, TX (US); Sandor Farkas, Round Rock, TX (US)

(21) Appl. No.: 15/017,165

(22) Filed: Feb. 5, 2016

(51) Int. Cl. H05K 3/40; H05K 3/42; H05K 3/00

(52) U.S. Cl. CPC H05K 3/4084; H05K 3/0047; H05K 3/429

(57) ABSTRACT

An electrical break is created in a via that would ordinarily electrically connect different layers of a printed circuit board. The electrical break severs the via into two or more separate and electrically disconnected vias. The electrical break may be placed at any depth along the via, thus demarking different purposes associated with different layers.

### FIELD OF THE DISCLOSURE

The present disclosure generally relates to electrical circuitry and, more particularly, to fabricating electrical vias in printed circuit boards.

### BACKGROUND

As the value and use of information continues to increase, individuals and businesses seek additional ways to process and store information. One option is an information handling system. An information handling system generally processes, compiles, stores, and/or communicates information or data for business, personal, or other purposes. Because technology and information handling needs and requirements may vary between different applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, reservations, enterprise data storage, or global communications. In addition, information handling systems may include a variety of hardware and software resources that may be configured to process, store, and communicate information and may include one or more computer systems, data storage systems, and networking systems.

Vias in printed circuit boards may cause signal reflections. As signals propagate along a via, stub regions may induce reflections that degrade signal integrity.

### SUMMARY

An electrical break is created in a via that would ordinarily electrically connect different layers of a printed circuit board. The electrical break severs the via into two or more separate and electrically disconnected vias. The electrical break may be placed at any depth along the via, thus demarking different purposes associated with different layers.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 illustrates a sectional view of a printed circuit board, according to exemplary embodiments;

FIGS. 2-7 illustrate fabrication of an electrical break, according to exemplary embodiments;

FIG. 8 illustrates an alternative drilling operation, according to exemplary embodiments;

FIG. 9 illustrates laser ablation, according to exemplary embodiments; and

FIG. 10 illustrates multiple electrical breaks, according to exemplary embodiments.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings, and is provided to assist in describing the teachings. This focus should not be interpreted as a limitation on the scope or applicability of the teachings.

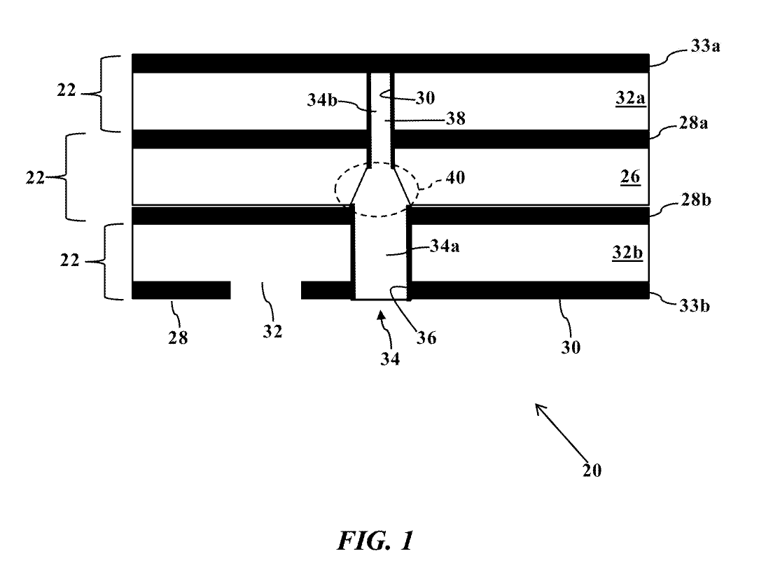

FIG. 1 shows a printed circuit board 20 that has multiple substrates 22 laminated together to form different layers 24. Some of the layers 24 may be very thin, perhaps having a thickness measured in thousandths or even millionths of a millimeter. FIG. 1 thus illustrates the different layers 24 in an enlarged view for clarity. Moreover, some of the layers 24 may be insulating, while other layers 24 may be electrically conducting. For example, the printed circuit board 20 may have an insulating inner core 26 sandwiched between conductive layers 28a and 28b (made from a conductive material 30 such as copper, although any conductive material may be used). Insulating pre-impregnated (or “pre-preg”) substrates 32a and 32b may be bonded thereto, and outer conductive foils 33a and 33b are applied. Any of the conductive members (e.g., the conductive layers 28a and 28b and the conductive foils 33a and 33b) may have electrical components and/or or traces etched therein. Chemical etching may expose the pre-preg substrate 32, although the outer conductive foils 33a and 33b may be removed by any other technique (such as photoengraving, photoresist, and mechanical milling). Because the printed circuit board 20 may have several or even many different layers 24, there may be one or more of the internal conductive layers 28 alternating with, or sandwiched between, adjacent insulating layers (e.g., the core 26 or the pre-preg substrate 32). The fabrication of the electrical circuit board 20 is generally known, so this disclosure need not dwell on the known aspects.

FIG. 1 also illustrates an electrical via 34. The via 34 interconnects any two or more of the conductive layers 28 and/or 33. The via 34 thus allows electrical signals to conduct from one conductive layer to another conductive layer. While the printed circuit board 20 may have many vias, for simplicity FIG. 1 only illustrates a single via 34. While the via 34 may have any diameter and length, the dimensions may again be measured in thousandths of a millimeter. FIG. 1 thus also illustrates the via 34 in an enlarged view for clarity. The via 34 may have a generally cylindrical inner surface 36 that may be at least partially coated with the conductive material 30 (such as electroplated copper). Once the inner surface 36 is plated or coated, the via 34 would conventionally have a single conductive inner barrel 38 that extends along the entire length of the via 34.

Here, though, exemplary embodiments electrically sever the via 34. That is, exemplary embodiments introduce or create an electrical break 40 at any desired location along the via 34. The via 34, in other words, lacks the conductive material 30 in the region of the electrical break 40, thus severing the conductive inner barrel 38 into two (2) or more electrically separate vias (illustrated as reference numerals 34a and 34b). As the electrical break 40 lacks the conductive material 30, the electrical break 40 produces an open circuit that will not propagate electrical signals (e.g., current and voltage) from the via 34a to the via 34b. The electrical break 40 thus reduces reflections of the signals that travel along either the via 34a and/or the via 34b. By altering the location of the electrical break 40, the vias 34a and 34b may be tuned or designed to flow signals to any particular one or more of the conductive layer(s) 28. The electrical break 40 may thus precisely demarcate and sever the conductive inner barrel 38 at a point that reduces or even eliminates signal reflections along the via 34.

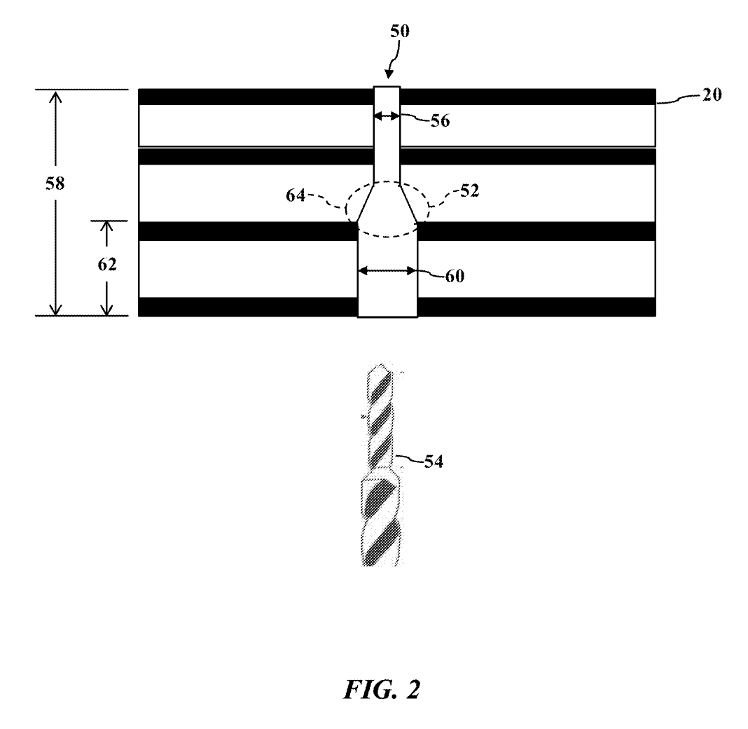

FIGS. 2-7 show the fabrication of the electrical break 40, including an initial drilling operation. The assembled printed circuit board 20 (commonly referred to as a “PCB assembly”) is installed or loaded into a drilling machine or fixture (not shown). A bare hole 50 is then initially fabricated into the PCB assembly 20. Here, though, the bare hole 50 has a stepped diameter 52. While the stepped diameter 52 may be created or machined using any mechanical or laser/heat removal process, FIG. 2 illustrates a stepped drill bit 54. As most readers are thought familiar with drilling and drill bits, the stepped drill bit 54 is thought easiest to understand. The stepped drill bit 54 thus bores the bare hole 50 having a first diameter 56 to a first depth 58. The stepped drill bit 54 also bores the bare hole 50 having a second diameter 60 to a second depth 62. The stepped drill bit 54 is then removed from the PCB assembly 20, thus revealing an internal transition step 64. A single drilling operation, in other words, produces the bare hole 50 having the differing diameters 56 and 60. The first diameter 56 and the second diameter 60 may differ in size, thus reducing or enlarging the bare hole 50 along a length (illustrated as the bored first depth 58). For example, FIG. 2 illustrates the first diameter 56 smaller than the second diameter 60, thus producing a region of the transition step 64.

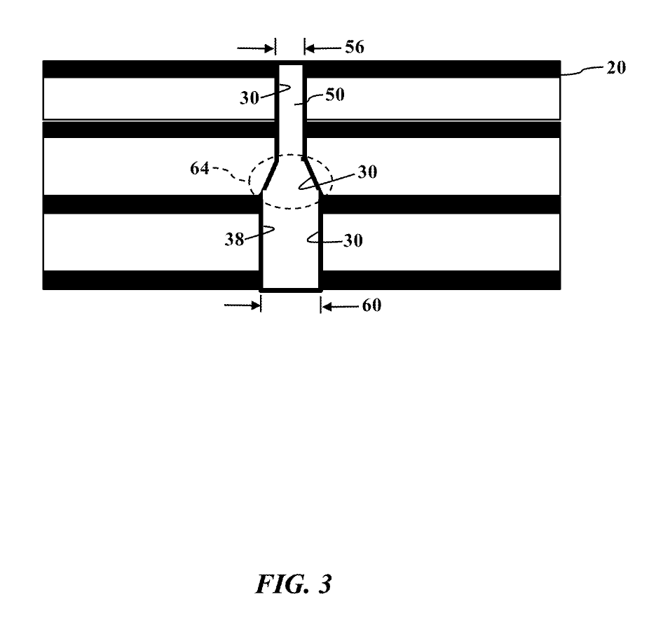

FIG. 3 illustrates a plating operation, according to exemplary embodiments. Once the bare hole 50 is bored, the single conductive inner barrel 38 is created. The inner surface 36 of the bare hole 50 may be electroplated with the conductive material 30, perhaps including the transition step 64 between the first diameter 56 and the second diameter 60. Exemplary embodiments, though, may utilize any process or material that makes the bare hole 50 electrically conductive.

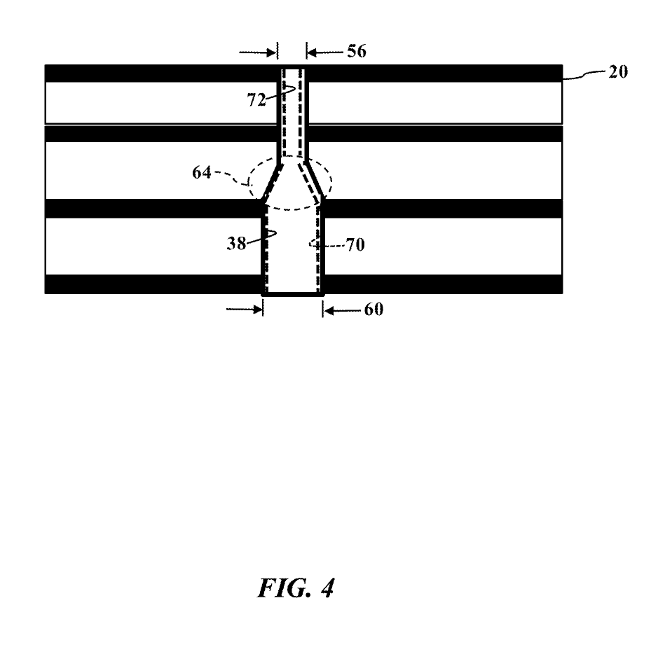

FIG. 4 illustrates another coating operation, according to exemplary embodiments. Once the conductive inner barrel 38 is created, a photoresistive coating 70 is applied. That is, an inner surface 72 of the conductive inner barrel 38 is coated with the photoresistive coating 70, including the transition step 64 between the first diameter 56 and the second diameter 60.

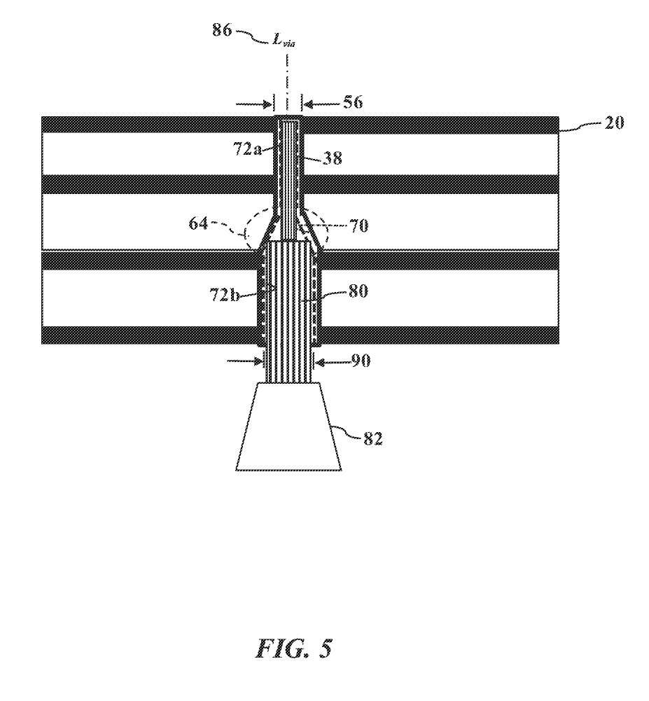

FIG. 5 illustrates ultraviolet exposure, according to exemplary embodiments. Now that the conductive inner barrel 38 is coated with the photoresistive coating 70, the transition step 64 is exposed to ultraviolet light 80. FIG. 5, for example, illustrates an ultraviolet emitter 82 emitting the ultraviolet light 80. Exemplary embodiments may align the output of the ultraviolet emitter 82 to a longitudinal axis (illustrated as reference numeral 86) of the conductive inner barrel 38 (and/or the previous bare hole 50 illustrated in FIG. 2). The ultraviolet light 80 thus propagates or travels down the conductive inner barrel 38. As the transition step 64 may be relatively unparallel or even perpendicular to the propagation path of the ultraviolet light 80, exemplary embodiments expose the photoresistive coating 70 applied to the transition step 64. The ultraviolet emitter 82 thus emits the ultraviolet light 80 down the conductive inner barrel 38. The ultraviolet emitter 82 may be focused at perhaps a beam diameter 88 slightly less than a largest or greatest coated diameter 90 of the conductive inner barrel 38. The ultraviolet light 80, however, need not be focused to a particular diameter. Regardless, because the ultraviolet light 80 propagates parallel to the longitudinal axis 86 of the conductive inner barrel 38, only the transition step 64 (and thus its locally applied photoresistive coating 70) is exposed to the ultraviolet light 80. The ultraviolet light 80 may soften or weaken the photoresistive coating 70, thus making the transition step 64 chemically vulnerable (e.g., positive photoresistive etching). However, the photoresistive coating 70 on the parallel inner surfaces 72a and 72b of the conductive inner barrel 38 remains unexposed to the ultraviolet light 80, so the photoresistive coating 70 in these areas hardens for protection. Some of the ultraviolet light 80 thus shines or propagates entirely along and through the conductive inner barrel 38 without incident exposure.

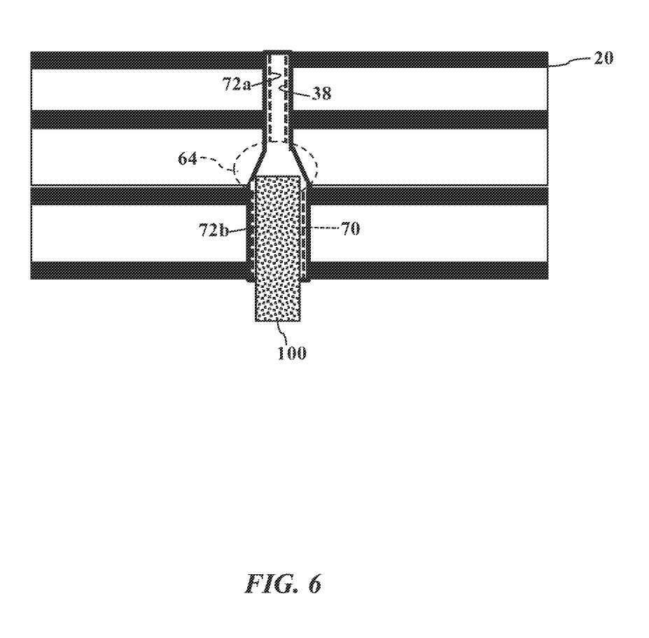

FIG. 6 illustrates a final etching process, according to exemplary embodiments. After the ultraviolet light 80 is fired down the conductive inner barrel 38 (as explained with reference to FIG. 5), a chemical etch 100 may be applied. The chemical etch 100 may be sprayed or injected into the conductive inner barrel 38, or the entire PCB assembly 20 may be bathed in the chemical etch 100. Chemical etching is generally known, so the details need not be explained. Suffice it to say the chemical etch 100 attacks any surface where the photoresistive coating 70 has been exposed to the ultraviolet light 80. The chemical etch 100 thus removes or washes away the photoresistive coating 70 that was previously applied to the transition step 64 (due to ultraviolet softening, as FIG. 5 illustrated). The chemical etch 100 thus chemically attacks and removes the underlying conductive material 30 in the transition step 64.

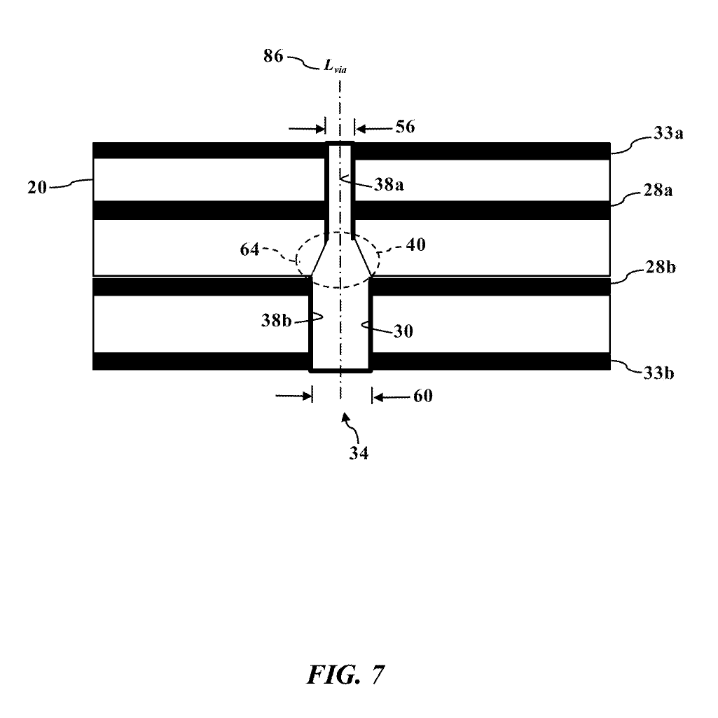

FIG. 7 thus illustrates the electrical break 40, according to exemplary embodiments. After the chemical etch 100 is applied (as explained with reference to FIG. 6), the conductive material 30 is removed from the transition step 64. The electrical break 40 is thus created or formed to split the conductive inner barrel 38. The via 34, in other words, now has two (2) different conductive inner barrels (illustrated as reference numerals 38a and 38b). The conductive inner barrels 38a and 38b may be concentric about the longitudinal axis 86, but the conductive inner barrels 38a and 38b are electrically isolated or disconnected from each other. Any electrical signals are thus prevented from propagating across electrical break 40. The depth of the transition step 64 (e.g., between the first diameter 56 and the second diameter 60) may thus be selectively chosen for optimum circuit design and/or performance goals.

Exemplary embodiments may thus be tunable. The electrical break 40 disrupts or breaks the electrical connection along the conductive inner barrel 38. Because the conductive material 30 is removed from the transition step 64, an open circuit is produced between the conductive inner barrels 38a and 38b. Electrical signals (e.g., current and voltage) may no longer propagate along the entire length of the via 34. That is, the electrical break 40 reduces reflections of the signals that travel along the electrical via 34. By altering the location of the transition step 64 (e.g., the transition from the first diameter 56 to the second diameter 60), the conductive inner barrels 38a and 38b may be tuned to flow signals to any particular conductive layer(s) 28 and/or 33. The electrical break 40 may thus precisely demarcate and sever the conductive inner barrel 38 at a point that reduces or even eliminates signal reflections along the via 34.

Exemplary embodiments need only remove a plating thickness. When the via 34 is plated (as explained with reference to FIG. 3), the plating process may also add a platting thickness to the exposed outer copper trace (illustrated as reference numerals 33a and 33b in FIG. 1). As ultraviolet ablating may be considered an etching process, exemplary embodiments may only need to etch deep enough to remove the platting thickness added to the via 34. The beam diameter 88 may thus be larger than the via barrel. The transition step 40 will be ablated and the added plating at the top of the via 34 would also be removed. Exemplary embodiments may thus top the ablation before blasting through the much thicker copper trace, thus not affecting electrical continuity into the via 34.

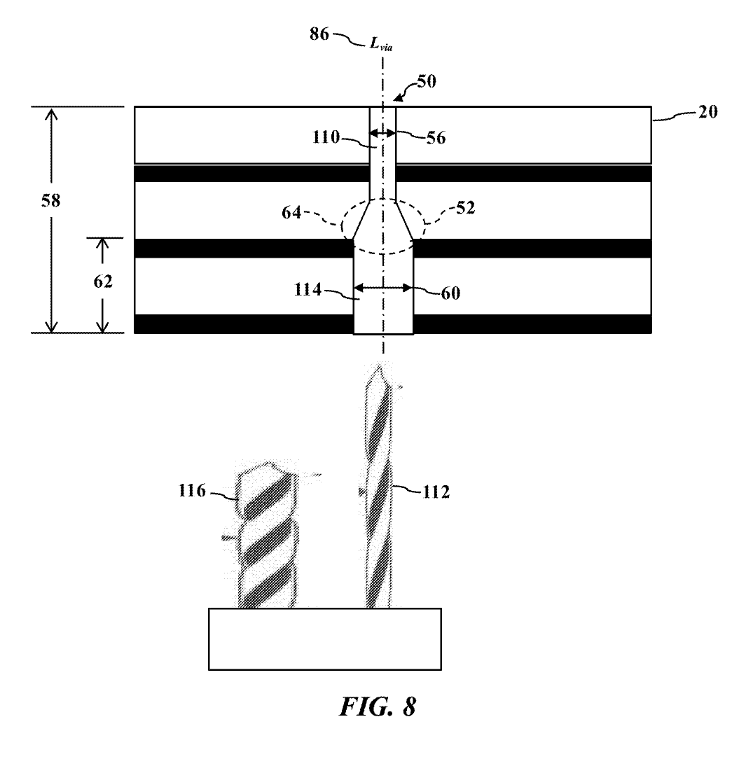

FIG. 8 illustrates another drilling operation, according to exemplary embodiments. Here the PCB assembly 20 may be counter drilled or bored to create the stepped bare hole 50. For example, the PCB assembly 20 may be installed or loaded into a drilling machine or fixture (not shown). A first hole 110 is initially drilled or bored into the PCB assembly 20 at the desired location of the via 34 (e.g., at the longitudinal axis Lᵥᵢₐ 86). FIG. 8, for simplicity, illustrates a first drill bit 112 having a diameter sized for the first diameter 56 to the first depth 58. Then a larger, second hole 114 is concentrically bored using a different, second drill bit 116. The second hole 114 may be bored at the second diameter 60 to the second depth 62. The second hole 114 is thus counter-bored to the desired second depth 62, at which the transition step 64 begins. The second hole 114, though, may be counter-bored without removing the PCB assembly 20 from the drilling machine or fixture. This counter bore, in other words, may be immediately and sequentially performed in the same bore direction after the first hole 110 is bored. The first drill bit 112 and the second drill bit 116, for example, may be commonly mounted or operated using a moving, sliding, and/or rotating carriage (not shown). Regardless, the PCB assembly 20 need not be removed from the drilling machine or fixture nor back drilled from a different direction. Operator time is reduced, processing steps are reduced, and hole alignment issues are avoided. Once the counter boring operation is complete, the PCB assembly 20 may be processed as explained with reference to FIGS. 3-6.

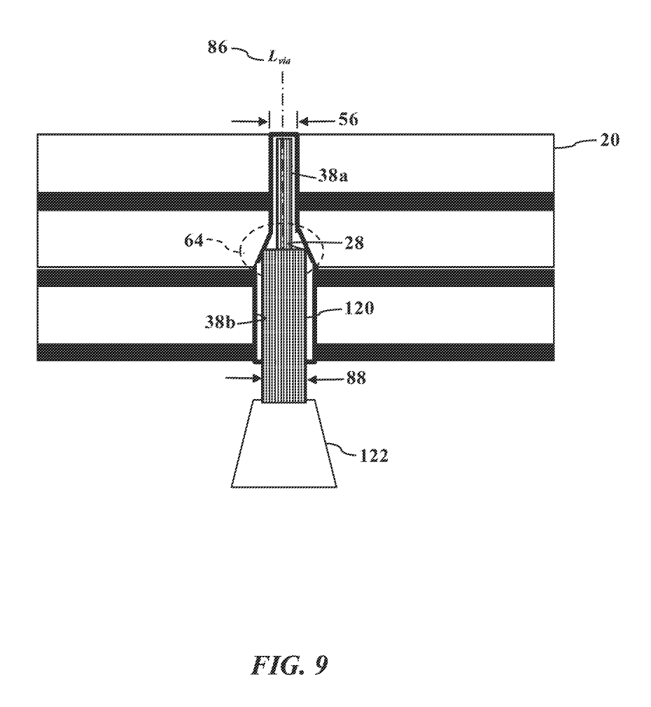

FIG. 9 illustrates laser ablation, according to exemplary embodiments. Here the electrical break 40 may be created by amplified light 120 aimed at the transition step 64. As FIG. 9 illustrates, the amplified light 120 may be beamed into and down the conductive inner barrel 38. The amplified light 120, for example, may be emitted from a laser 122. The optical output of the laser 122 is preferably aligned to the longitudinal axis 86 of the conductive inner barrel 38. The amplified light 120 thus propagates or travels down the conductive inner barrel 38 and strikes the incident surface of the transition step 64. The amplified light 120 (perhaps having an appropriate color, power, and/or frequency) thus removes, burns, or ablates the conductive material 30 coating the transition step 64. Again, if the beam diameter 88 is slightly less than the conductive inner barrel 38, the amplified light 120 propagates parallel to the longitudinal axis 86 and removes the conductive material 30 from the transition step 64. The electrical break 40 thus creates the two (2) different conductive inner barrels 38a and 38b. The conductive inner barrels 38a and 38b are concentric but electrically isolated or disconnected from each other. Any electrical signals are thus prevented from propagating across electrical break 40.

Exemplary embodiments may thus repurpose existing laser processing. Carbon dioxide lasering is sometimes currently used to create “blind” vias in printed circuit boards. A CO₂ laser, in other words, is already used to burn shallow depth vias. As the CO₂ laser may already be present in some or many PCB fabrication lines, exemplary embodiments may repurpose the existing CO₂ laser to create the electrical break 40 in deeper vias (such as the via 34 illustrated in FIG. 9). Exemplary embodiments, in other words, may leverage any existing lasering station to create the electrical break 40. The PCB assembly 20 is merely delivered or moved to the existing lasering station and the amplified light 120 (perhaps output from the existing CO₂ laser) is beamed into and down the conductive inner barrel 38. The amplified light 120 ablates the conductive material 30 that coats the transition step 64 (again assuming the correct beam diameter 88 and parallel propagation, as above explained). The electrical break 40 thus creates the two (2) different conductive inner barrels 38a and 38b. The existing laser operation for creating blind vias may thus be dual-purposed to create the electrical break 40 without special fixturing or tooling.

Light alignment may be necessary. The beam diameter 88 of the ultraviolet light 80 and/or the amplified light 120 may need to be less than the remaining diameter after plating. The bare hole 50, for example, is first bored and then electroplated with the conductive material 30. The conductive material 30 will thus have a thin film thickness that reduces the bored diameter 56 and 60. One may assume the conductive material 30 is relatively or substantially uniformly applied, so that the bored diameters 56 and 60 are reduced according to two times the plating thickness. The beam diameter 88 may thus be chosen to account for the thickness of the conductive material.

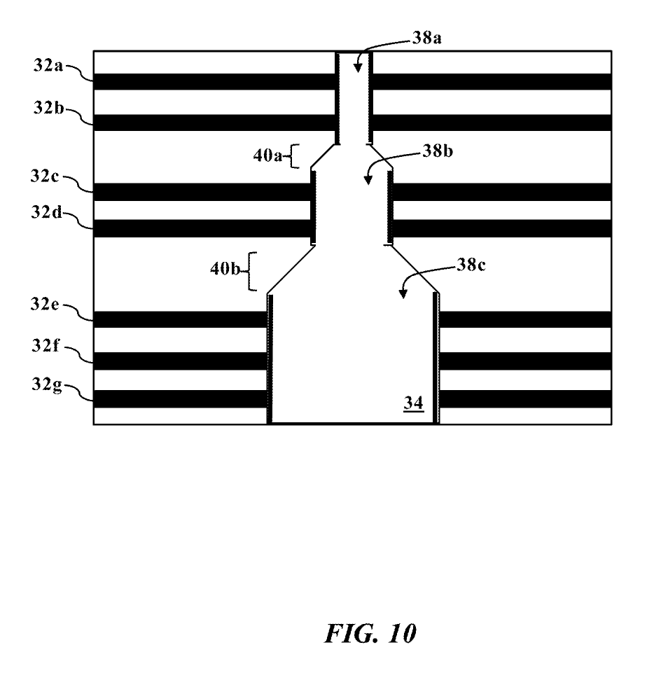

FIG. 10 illustrates multiple electrical breaks 40, according to exemplary embodiments. Here exemplary embodiments may split the via 34 into three (3) or even more separate conductive inner barrels. FIG. 10, for example, illustrates the via 34 having a triple step boring that creates three (3) electrically separate conductive inner barrels 38a, 38b, and 38c. Each one of the different conductive inner barrels 38a, 38b, and 38c may thus have a different electrical purpose. For example, the via 34 may have a first electrical break 40a that only creates an interconnect between a first pair of the conductive layers 32a and 32b. The via 34 may have a second electrical break 40b that only creates an interconnect between different conductive layers 32c and 32d. Indeed, more than two (2) layers may be electrically connected, such as the inner conductive barrel 38c electrically connecting still more different conductive layers 32e, 32f, and 32g. The placement or location of each electrical break 40 may thus be chosen to electrically interconnect any conductive layers, whether interior and/or exterior. Exemplary embodiments, in other words, may double, triple, or even greatly increase a density of the vias. A single drilling operation/station may thus provide multiple steps for interconnecting internal traces while eliminating the stub from both sides.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

What is claimed is:

1. A method, comprising:
boring a stepped hole into a printed circuit board assembly, the stepped hole having a transition step from a first diameter to a second diameter;
plating an inner surface of the step hole with an electrically conductive material to create an electrical via, the electrical via electrically connecting different conductive layers in the printed circuit board assembly; and
removing the electrically conductive material from the transition step to create an electrical break in the electrical via.

2. The method of claim 1, further comprising severing the electrical via at the electrical break to create electrically separate barrels.

3. The method of claim 1, further comprising boring the stepped hole in a single drilling operation.

4. The method of claim 1, further comprising electrically connecting the electrical via to an outer layer of the printed circuit board assembly.

5. The method of claim 1, further comprising boring the stepped hole to a depth in the printed circuit board assembly.

6. The method of claim 1, further comprising boring the stepped hole into an insulating layer of the printed circuit board assembly.

7. The method of claim 1, further comprising boring the stepped hole to a conductive layer of the printed circuit board assembly.

8. A method, comprising:
boring a stepped hole into a printed circuit board assembly, the stepped hole having a transition step from a first diameter to a second diameter;
plating an inner surface of the step hole with an electrically conductive material to create an electrical via, the electrical via electrically connecting different conductive layers in the printed circuit board assembly; and
etching the electrically conductive material from the transition step to create an electrical break in the electrical via.

9. The method of claim 8, further comprising applying a photoresistive coating to the electrically conductive material.

10. The method of claim 9, further comprising exposing the transition step to ultraviolet light to weaken the photoresistive coating applied thereto.

11. The method of claim 8, further comprising severing the electrical via at the electrical break to create electrically separate barrels.

12. The method of claim 8, further comprising boring the stepped hole in a single drilling operation.

13. The method of claim 8, further comprising boring the stepped hole to a depth in the printed circuit board assembly.

14. The method of claim 8, further comprising boring the stepped hole into an insulating layer of the printed circuit board assembly.

15. The method of claim 8, further comprising boring the stepped hole to a conductive layer of the printed circuit board assembly.

16. A method, comprising:
boring a stepped hole into a printed circuit board assembly, the stepped hole having a transition step from a first diameter to a second diameter;
plating an inner surface of the step hole with an electrically conductive material to create an electrical via, the electrical via electrically connecting different conductive layers in the printed circuit board assembly; and
ablating the electrically conductive material from the transition step to create an electrical break in the electrical via.

17. The method of claim 16, further comprising beaming amplified light along the electrical via, the amplified light ablating the electrically conductive material from the transition step.

18. The method of claim 16, further comprising beaming amplified light along the electrical via, the amplified light aligned with a longitudinal axis of the electrical via, the amplified light having a beam diameter sized to only ablate the electrically conductive material from the transition step.

19. The method of claim 16, further comprising severing the electrical via at the electrical break to create electrically separate barrels.

20. The method of claim 16, further comprising boring the stepped hole in a single drilling operation.
